(19) United States
(12) Patent Application Publication
(10) Pub. No.: US 2008/0076247 A1
(43) Pub. Date: Mar. 27, 2008

(54) METHOD OF FORMING INTER-METAL DIELECTRIC LAYER IN A SEMICONDUCTOR DEVICE

(75) Inventor: Sang Deok KIM, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/769,307

(22) Filed: Jun. 27, 2007

(30) Foreign Application Priority Data
Sep. 22, 2006 (KR) 10-2006-92351

(51) Int. Cl. H01L 21/44

(52) U.S. Cl. 438/669; 257/E21.476

(57) ABSTRACT

A method of forming an inter-metal dielectric layer in a semiconductor device is disclosed. A metal wire is patterned on a semiconductor substrate. A buffer oxide layer and a material layer form an inter-metal dielectric layer on a resulting surface of the metal wire and the semiconductor substrate in an in-situ manner. A portion of the metal wire is etched when the inter-metal dielectric layer is formed to prevent generation of an abnormal layer between the metal wires, thereby preventing degradation of operational characteristics of the device.

### CROSS-REFERENCES TO RELATED APPLICATIONS

The present application claims priority to Korean patent application number 10-2006-92351, filed on Sep. 22, 2006, which is incorporated by reference in its entirety.

### BACKGROUND OF THE INVENTION

The present invention relates to a method of forming an inter-metal dielectric layer in a semiconductor device, and more particularly, to a method of forming an inter-metal dielectric layer in a semiconductor device that prevents the generation of undesirable substances between metal wires.

In a semiconductor device, an inter-metal dielectric layer is formed between metal layers to isolate the metal layers from each other. The inter-metal dielectric layer is formed using several processes. Since an aspect ratio increases as the semiconductor device becomes highly integrated, the inter-metal dielectric layer is formed using a plasma enhanced chemical vapor deposition process which is favorable for the micro pattern.

FIG. 1 is a sectional view of a semiconductor device illustrating a conventional method of forming an inter-metal dielectric layer of a semiconductor device.

Tungsten, which is a material used for forming a metal wire, is deposited on a semiconductor substrate 10 and then patterned to form a metal wire 11. An inter-metal dielectric layer 12 is then formed on the entire structure. A high density plasma (HDP) oxide layer having an excellent gap filling characteristic is commonly utilized as the inter-metal dielectric layer 12. However, HDP oxide is a substance which is deposited and etched simultaneously such that a portion of the metal wire 11 is also etched.

The HDP oxide is deposited using a high bias power to fill a space between the metal wires 11. Plasma is collided with the metal wire at a high energy so that a portion of the metal wire is etched. Impurities generated by etching accumulate in a space between the metal wires to form a thin abnormal layer 13. Since the abnormal layer 13 is made of the same material as the metal wire 11 (e.g., tungsten), the abnormal layer creates a micro bridge between the micro wires 11 to adversely impact operational characteristics of the device.

### SUMMARY OF THE INVENTION

A method of forming an inter-metal dielectric layer in a semiconductor device is disclosed. A metal wire is patterned on a semiconductor substrate. A buffer oxide layer and material layer form an inter-metal dielectric layer on a resulting surface of the metal wire and the semiconductor substrate in an in-situ manner. A portion of the metal wire is etched when the inter-metal dielectric layer is formed to prevent generation of an abnormal layer between the metal wires, thereby preventing degradation of operational characteristics of the device.

The method of forming an inter-metal dielectric layer in a semiconductor device according to one embodiment of the present invention comprises forming a metal layer on a semiconductor substrate. The metal layer is patterned to form a metal wire. A buffer layer is formed on the resulting surface of the semiconductor substrate and the metal wire. An inter-metal dielectric layer is formed on the buffer layer. The buffer layer prevents plasma damage from occurring when forming the inter-metal dielectric layer.

In one aspect of the invention, the buffer layer includes an oxide layer. The metal layer includes tungsten. The buffer layer is formed with a material having a low compressive force or a low tensile stress. The buffer layer is formed using a bias power of 0.1 W to 1,000 W. The buffer layer is formed to have a thickness of 50 Å to 500 Å. The inter-metal dielectric layer is formed using a high density plasma chemical vapor deposition (HDP CVD) method. The inter-metal dielectric layer includes a silicon oxide layer. The inter-metal dielectric layer is formed using a bias power of 500 W to 4,000 W. The inter-metal dielectric layer is formed to have a thickness of 1,000 Å to 20,000 Å.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a sectional view of a semiconductor device illustrating a conventional method of forming an inter-metal dielectric layer of a semiconductor device; and

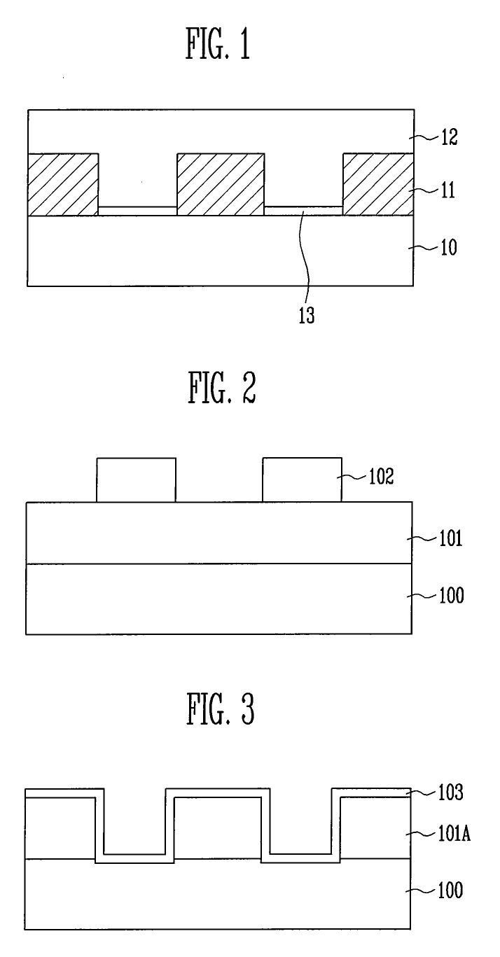

FIG. 2 to FIG. 4 are sectional views of a semiconductor device illustrating a method of forming an inter-metal dielectric layer of a semiconductor device according to an embodiment of the present invention.

### DESCRIPTION OF SPECIFIC EMBODIMENTS

Hereinafter, the preferred embodiment of the present invention will be described in detail with reference to the accompanying drawings. However, the present invention is not limited to the embodiment disclosed, and can be variously modified. The embodiment is provided for illustrating more completely the present invention to those skilled in the art and a scope of the present invention should be understood from the appended claims.

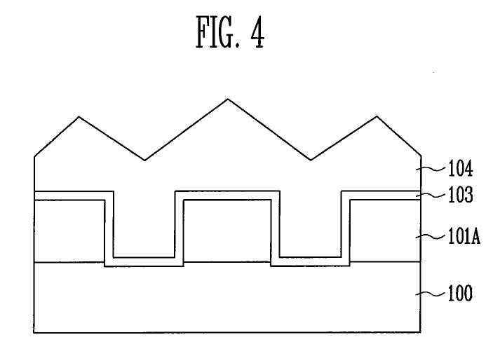

FIG. 2 to FIG. 4 are sectional views of a semiconductor device illustrating a method of forming an inter-metal dielectric layer of a semiconductor device according to an embodiment of the present invention.

Referring to FIG. 2, material 101 used for forming a metal wire is deposited on a semiconductor substrate 100. It is preferred that tungsten is utilized as the material 101 for forming the metal wire. A photoresist pattern 102 is then formed on the material 101 for patterning a metal wire.

Referring to FIG. 3, an etching process is performed utilizing the photoresist pattern 102 as an etch mask. The material 101 for a metal wire is etched to expose the semiconductor substrate 100 and to form the metal wire 101A. A buffer oxide layer 103 is then formed on the resulting surface including the semiconductor substrate 100 and the metal wire 101A to prevent plasma damage when an inter-insulating layer is subsequently formed. It is desirable to form the buffer oxide layer 103 using material having a low compressive force or a low tensile stress. It is also desirable to form the buffer oxide layer 103 using a bias power of 0.1 W to 1,000 W. In addition, it is preferable that the buffer oxide layer 103 is formed to have a thickness of 50 Å to 500 Å.

Referring to FIG. 4, an inter-metal dielectric layer 104 is formed on the buffer oxide layer 103 in an in-situ manner. Compared with a conventional process, the process for forming the inter-metal dielectric layer 104 in the in-situ manner is performed without increasing processing time. If the process for forming the inter-metal dielectric layer 104 is not performed in the in-situ manner, an additional processing time of approximately four hours or more may be required.

It is desirable to form the inter-metal dielectric layer 104 through a high density plasma chemical vapor deposition (HDP CVD) method. By forming the inter-metal dielectric layer 104 using the high density plasma chemical vapor deposition method, a space between the metal wires 101A is completely filled with the inter-metal dielectric layer 104 without generating a seam.

It is desirable that the inter-metal dielectric layer 104 is formed of a silicon oxide layer. It is also desirable to form the inter-metal dielectric layer 104 using a bias power of 500 W to 4,000 W. In addition, it is preferable that the inter-metal dielectric layer 104 is formed to have a thickness of 1,000 Å to 20,000 Å.

Since the buffer oxide layer 103 surrounds all of the metal wire 101A, it is possible to prevent plasma damage caused by a high bias voltage when forming the inter-metal insulating layer 104. Accordingly, a portion of the metal wire 101A is etched such that formation of a bridge caused by an abnormal layer formed between the metal wires 101A can be prevented.

Although the technical spirit of the present invention has been concretely described in connection with the preferred embodiment, the scope of the present invention is not limited by the specific embodiments, but should be construed by the appended claims. Further, it should be understood by those skilled in the art that various changes and modifications can be made thereto without departing from the scope of the present invention.

According to an embodiment of the present invention, a metal wire is patterned on a semiconductor substrate. A buffer oxide layer and a material layer form an inter-metal dielectric layer on a resulting surface of the metal wire and the semiconductor substrate in an in-situ manner. A portion of the metal wire is etched when the inter-metal dielectric layer is formed to prevent generation of an abnormal layer between the metal wires, thereby preventing degradation of operational characteristics of the device.

What is claimed is:

1. A method of forming an inter-metal dielectric layer in a semiconductor device, the method comprising:
forming a metal layer over a semiconductor substrate;
patterning the metal layer to form a metal wire;
forming a buffer layer over a resulting surface of the semiconductor substrate and the metal wire; and
forming an inter-metal dielectric layer over the buffer layer, wherein the buffer layer prevents plasma damage from occurring when forming the inter-metal dielectric layer.

2. The method of forming the inter-metal dielectric layer in the semiconductor device according to claim 1, wherein forming the buffer layer and forming the inter-metal dielectric layer are performed in an in-situ manner.

3. The method of forming the inter-metal dielectric layer in the semiconductor device according to claim 1, wherein the buffer layer comprises an oxide layer.

4. The method of forming the inter-metal dielectric layer in the semiconductor device according to claim 1, wherein the metal layer comprises tungsten.

5. The method of forming the inter-metal dielectric layer in the semiconductor device according to claim 1, wherein the buffer layer is formed with a material having a low compressive force or a low tensile stress.

6. The method of forming the inter-metal dielectric layer in the semiconductor device according to claim 1, wherein the buffer layer is formed using a bias power of approximately 0.1 W to 1,000 W.

7. The method of forming the inter-metal dielectric layer in the semiconductor device according to claim 1, wherein the buffer layer is formed to have a thickness of approximately 50 Å to 500 Å.

8. The method of forming the inter-metal dielectric layer in the semiconductor device according to claim 1, wherein the inter-metal dielectric layer is formed using a high density plasma chemical vapor deposition (HDP CVD) method.

9. The method of forming the inter-metal dielectric layer in the semiconductor device according to claim 1, wherein the inter-metal dielectric layer comprises a silicon oxide layer.

10. The method of forming the inter-metal dielectric layer in the semiconductor device according to claim 1, wherein the inter-metal dielectric layer is formed using a bias power of approximately 500 W to 4,000 W.

11. The method of forming the inter-metal dielectric layer in the semiconductor device according to claim 1, wherein the inter-metal dielectric layer is formed to have a thickness of approximately 1,000 Å to 20,000 Å.
